(19) United States
(12) Patent Application Publication
(10) Pub. No.: US 2006/0088986 A1
(43) Pub. Date: Apr. 27, 2006

(54) Method of enhancing laser crystallization for polycrystalline silicon fabrication

(76) Inventors: Jia-Xing Lin, Panchiao City (TW); Chi-Lin Chen, Hsinchu City (TW); Yu-Cheng Chen, Hsinchu City (TW); Po-Hao Tsai, Panchiao City (TW)

Correspondence Address: RABIN & BERDO, P.C.;Suite 500, 1101 14 Street, N.W., Washington, DC, 20005, US

(21) Appl. No.: 11/222,804

(22) Filed: Sep. 12, 2005

(30) Foreign Application Priority Data
Oct. 22, 2004 (TW) 93132223

(51) Int. Cl. H01L 21/20

(52) U.S. Cl. 438/482; 438/486

(57) ABSTRACT

An amorphous silicon layer and at least a heat-retaining layer are formed on a substrate in turn. Wherein, the heat-retaining layer is controlled to have an anti-reflective thickness for reducing the threshold laser energy to effect the melting of the amorphous silicon layer. Then, a laser irradiation process is performed to transform the amorphous silicon layer into a polycrystalline silicon layer. During the laser irratiation process, a portion of the laser energy transmits the heat-retaining layer to effect the melting of the amorphous silicon layer, and another portion of the laser energy is absorbed by the heat-retaining layer.

### RELATED APPLICATIONS

The present application is based on, and claims priority from, Taiwan Application Serial Number 93132223, filed Oct. 22, 2004, the disclosure of which is hereby incorporated by reference herein in its entirety.

### FIELD OF THE INVENTION

The present invention relates to a method of enhancing laser crystallization, and more particularly, to a method of enhancing laser crystallization by a heat-retaining layer with an anti-reflectivity function for polycrystalline silicon fabrication.

### BACKGROUND OF THE INVENTION

Polycrystalline silicon thin film as a high quality active layer in semiconductordevices has lately attracted considerable attention due to its superior charge carrier transport property; and high compatibility with current semiconductor device fabrication. With low temperature process, it is possible to fabricate reliable polycrystalline silicon thin film transistors (TFTs) on transparent glass or plastic substrates for making polycrystalline silicon more competitive in the application of large area flat panel displays such as active matrix liquid crystal displays (AMLCDs) or active matrix organic light emitting diode displays (OLEDs).

The importance of polycrystalline silicon TFTs comprises a superior display performance such as high pixel aperture ratio, low driving power consumption, and device reliability; and further more, an enabling feature of integrating various peripheral driver components directly onto the glass substrate. Peripheral circuit integration is not only beneficial in reducing the running cost, but also in enriching the functionality for mobile purpose applications. However, the device performance of polycrystalline silicon TFTs, such as carrier mobility, is significantly affected by the crystal grain size. The carrier flow in an active channel has to overcome the energy barrier of the grain boundary between each crystal grain, and thus the carrier mobility decreases. Therefore, in order to improve the device performance, it is very important to reduce the number of polycrystalline silicon grain boundaries within the active channel. To fulfill the requirement, grain size enlargement and grain boundary location control within the active channel are the two possible manipulations.

The conventional methods for fabricating polycrystalline silicon thin film comprises solid phase crystallization (SPC) and direct chemical vapor phase deposition (CVD). Those techniques are not applicable to high performance flat panel displays because the crystalline quality is limited by the low process temperature (typically lower than 650° C.), and the grain size of polycrystalline silicon is as small as 100 nm. Hence, the electrical characteristics of polycrystalline silicon thin film are limited.

The excimer laser annealing (ELA) method is currently the most commonly used method in polycrystalline silicon TFT fabrication. The grain size of polycrystalline silicon thin film can reach 300-600 nm, and the carrier mobility of polycrystalline silicon TFTs can reach 200 cm²/V-s. However, this value is yet not sufficient for future demand of high performance flat panel displays. Besides, unstable laser energy output of ELA narrows down the process window generally to several tens of mJ/cm². Therefore, frequently repeated laser irradiation is necessary to re-melt imperfect fine grains caused by the irregular laser energy fluctuation. But, repeated laser irradiation makes ELA less competitive due to its high cost in process optimization and system maintenance.

Although a few methods for enlarging grain size of polycrystalline silicon have been set forth recently, these methods such as sequential lateral solidification (SLS) and phase modulated ELA (PMELA), all still require additional modification and further process parameter control for the current ELA systems.

### SUMMARY OF THE INVENTION

An objective of the present invention is to provide a method of enhancing laser crystallization for polycrystalline silicon fabrication, which method can be applied to polycrystalline silicon thin film transistor (TFT) fabrication. A heat-retaining layer is used to enhance laser crystallization by lengthening the melting time of the amorphous silicon, hence high quality crystal grains with large grain size are obtained after laser irradiation. Besides, a heat-retaining layer with an anti-reflective thickness is formed for more efficient laser energy use, and the laser energy to effect the melting of the amorphous silicon is further reduced.

According to the aforementioned objectives of the present invention, a method of enhancing laser crystallization for polycrystalline silicon fabrication is provided. According to one preferred embodiment of this invention, an amorphous silicon layer is first formed on a substrate, and at least one heat-retaining layer is formed on the amorphous silicon layer. The heat-retaining layer has an anti-reflective thickness for reducing the threshold laser energy to effect the melting of the amorphous silicon. Then, a laser irradiation process is performed to transform the amorphous silicon layer into a polycrystalline silicon layer.

The heat-retaining layer is a semitransparent film such as silicon oxynitride (SiOₓN_{y}). After laser irradiation, a portion of laser energy transmits the heat-retaining layer to effect the melting of the amorphous silicon layer, while another portion is absorbed by the heat-retaining layer to continuously heat the melted amorphous silicon layer. Besides, the anti-reflective thickness is not a constant and usually a function of material optical parameters and laser light wavelength. For example, a preferred anti-reflective thickness in the present embodiments of this invention is about 1300, 2200, 3100, 4000, 4900, or 5800 Å. Moreover, the laser irradiation process is performed by a XeCl excimer laser light source.

Because the threshold energy to effect the melting of the amorphous silicon layer is reduced by the anti-reflective thickness control, the lower laser energy such as 200-900 mJ/cm² is sufficient to be used to melt the amorphous silicon layer for crystallization.

Additionally, another heat-retaining layer with another anti-reflective thickness and suitable dielectric capability, for example, a Silicon dioxide (SiO₂) layer, can be interlaid between the amorphous silicon layer and the heat-retaining layer as a dielectric interlayer having a heat-retaining function. Then, the top heat-retaining layer is removed after the laser irradiation process, and the heat-retaining layer serving as a dielectric interlayer remains. Next, the general TFT manufacturing process is applied to finish the TFT device fabrication.

Alternatively, a SiOₓN_{y} layer is formed with suitable dielectric capability by controlling a composition ratio of SiOₓN_{y}. The SiOₓN_{y} layer can be as a heat-retaining layer and a dielectric interlayer simultaneously. Thus, whether forming a single SiOₓN_{y} heat-retaining layer, double SiOₓN_{y} heat-retaining layers, or multiple SiOₓN_{y} heat-retaining layers on the amorphous silicon layer, the general TFT fabrication process can be used to finish the TFT fabrication directly after the laser irradiation process without removing any heat-retaining layer.

With the application of the present invention, grain growth of amorphous silicon crystallization is enhanced by an additional heating function from the heat-retaining layer, and the laser energy density used in the laser irradiation process to effect the melting of the amorphous silicon layer is reduced by the anti-reflective thickness design of the heat-retaining layer. Therefore, a laser crystallization effect is improved greatly to obtain polycrystalline silicon with large grains in a general laser irradiation process. Besides, the laser energy is utilized more effectively. Moreover, laser energy distribution absorbed in the amorphous silicon layer is more uniform because of the heat-retaining layer formation, and a frequently repeated laser operation in the conventional laser process is thus avoided. A single shot laser is sufficient to achieve a good crystallization result. At the same time, the process window of laser energy control is further broadened.

Furthermore, since the laser energy density to effect the melting of the amorphous silicon layer is reduced by the anti-reflective thickness design, the irradiative area of a single shot laser can be increased. Therefore, the frequency or the total number of laser shot used is decreased, and more particularly, the frequency or the total number of laser shot used is decreased more effectively for reducing the cost in large area TFT-LCD fabrication.

According to the aforementioned advantages of the invention, a polycrystalline silicon layer with several micrometers grain size is obtained by employing the present invention, and laser crystallization quality is thus improved obviously for fabricating TFT with good quality and higher electrical performance.

### BRIEF DESCRIPTION OF THE DRAWING

The foregoing aspects and many of the attendant advantages of this invention will become more readily appreciated as the same becomes better understood by reference to the following detailed description, when taken in conjunction with the accompanying drawings, wherein:

FIG. 1 is a flowchart showing the process for enhancing laser crystallization in accordance with the first preferred embodiment of the present invention;

FIGS. 2A-2B are cross-sectional schematic diagrams showing the process for enhancing laser crystallization in accordance with the first preferred embodiment of the present invention;

FIG. 3 is a graph showing the relationship between the heat-retaining layer thickness and the complete melting threshold energy of amorphous silicon in accordance with the first preferred embodiment of the present invention;

FIGS. 4A-4B are cross-sectional schematic diagrams showing the process for enhancing laser crystallization in accordance with the second preferred embodiment of the present invention; and

FIG. 5 is a cross-sectional schematic diagram showing the structure of the polycrystalline silicon thin film transistor in accordance with the second preferred embodiment of the present invention.

### DETAILED DESCRIPTION OF THE PREFERRED EMBODIMENTS

Because a XeCl laser with 308 nm wavelength is usually used for polycrystalline silicon fabrication, a heat-retaining layer with a good anti-reflectivity to laser light with 308 nm wavelength is formed by employing the preferred embodiments of the present invention to cap the amorphous silicon layer for enhancing laser crystallization in polycrystalline silicon fabrication technology. Besides, an anti-reflective thickness of the heat-retaining layer is controlled to reduce laser energy used for crystallization, and the process window of laser energy control is also broadened. Therefore, enhanced laser crystallization of the amorphous silicon layer is obtained from the heat-retaining function of the heat-retaining layer and useful to form polycrystalline silicon with large grains.

### Embodiment 1

The present invention discloses a method of enhancing laser crystallization for polycrystalline silicon fabrication. A semitransparent material is used as the heat-retaining layer capped on the amorphous silicon layer to lengthen the amorphous silicon melting time in a laser irradiation process. When the laser irradiation process is performed, a portion of the laser energy passes through the heat-retaining layer to effect the melting of the amorphous silicon layer, while another portion is absorbed by the heat-retaining layer to continuously heat the melted amorphous silicon layer and hence lengthen the cooling time of melted amorphous silicon. Crystallization of the amorphous silicon layer is thus improved to further enhance grain growth for forming a high quality polycrystalline silicon layer with large grains.

However, the heat-retaining layer is not only semitransparent, but reflects incident laser light in general, so the laser energy used cannot be transmitted to the amorphous silicon layer completely, and portions of the laser light are reflected when the laser irradiates the heat-retaining layer. Therefore, the laser light can be utilized more fully if the reflective effect is reduced, and laser crystallization is then enhanced.

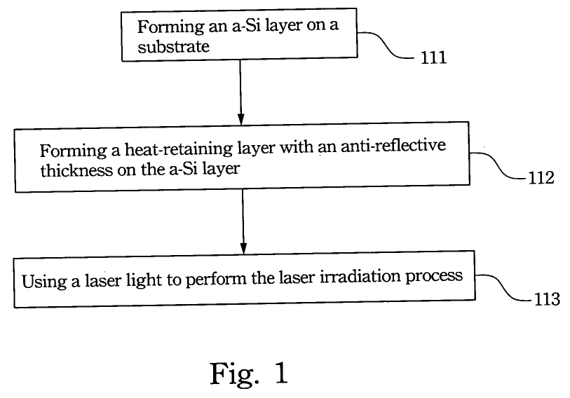

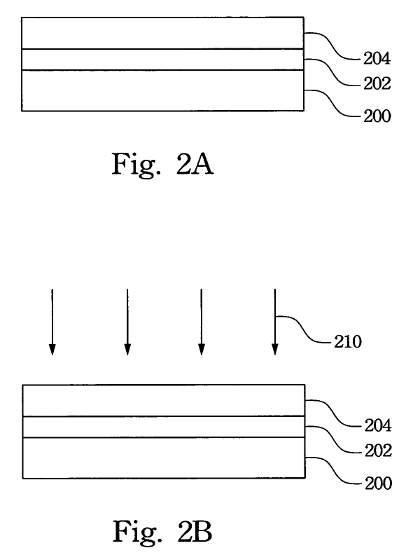

Referring to FIG. 1 and FIGS. 2A-2B, wherein FIG. 1 is a flowchart showing the process for enhancing laser crystallization in accordance with the first preferred embodiment of the present invention, and FIGS. 2A-2B are cross-sectional schematic diagrams showing the process for enhancing laser crystallization in accordance with the first preferred embodiment of the present invention. First, a step 111 in FIG. 1 for forming an amorphous silicon layer 202 is performed, wherein the amorphous silicon layer 202 is formed on a substrate 200 by, for example, plasma enhanced chemical vapor phase deposition (PECVD) or physical vapor deposition (PVD). The substrate 200 may be a glass substrate for display fabrication, and the preferred thickness of the amorphous silicon layer 202 is about 50 nm. Further, dehydrogenation is then performed on the amorphous silicon layer 202 to prevent a hydrogen explosion during the subsequent laser irradiation.

Next, a step 112 in FIG. 1 is performed to form a heat-retaining layer 204 with an anti-reflective thickness on the amorphous silicon layer 202 in FIG. 2A, and the heat-retaining layer 204 has good anti-reflectivity to laser light by controlling the anti-reflective thickness of the heat-retaining layer 204. Wherein the heat-retaining layer 204 is a semitransparent material such as silicon oxynitride (SiOₓN_{y}), and the heat-retaining layer 204 may be formed by PECVD.

Finally, a step 113 in FIG. 1 is performed, and a laser light 210 in FIG. 2B is used to perform the laser irradiation process. Wherein, the laser light 210 is, for example, a XeCl excimer laser. When the laser light 210 irradiates the heat-retaining layer 204, a portion of the laser light 210 passes through the heat-retaining layer 204 to melt the amorphous silicon layer 202 directly, while another portion of the laser light 210 is absorbed by the heat-retaining layer 204 and thus heats the melted amorphous silicon layer 202 continuously. Laser energy is transmitted to the amorphous silicon layer 202 more uniformly at the same time. Therefore, crystallization time of the amorphous silicon layer 202 is lengthened to enlarge grain growth, and laser energy absorbed by the amorphous silicon layer 202 is more uniform, even though the uniformity of laser energy distribution in the laser light 210 is not so good.

Additionally, the reflectivity or anti-reflectivity of the heat-retaining layer 204 is affected by different thickness of the heat-retaining layer 204, and the threshold energy to effect the melting of the amorphous silicon layer 202 is affected simultaneously. Degree of the laser light 210 reflected by the heat-retaining layer 204 is reduced when the heat-retaining layer 204 has a higher anti-reflectivity, so the heat-retaining layer 204 and the amorphous silicon layer 202 both absorb more complete laser energy from the laser light 210. Thus, the threshold energy to effect the melting of the amorphous silicon layer 202 is reduced for lowering the actual laser energy used directly, and laser energy kept inside the heat-retaining layer 204 is increased for improving the additional heating function to the amorphous silicon layer 202. Therefore, melting and cooling time of the amorphous silicon layer 202 is much longer, and grain growth in the melted amorphous silicon for crystallization is further enhanced greatly.

According to the general theory of reflection, various materials with different reflectivity or light sources with different wavelength have different reflection behaviors, and reflection behavior is also affected by material thickness. For one material, the relation between thickness and reflectivity is a periodic variation; a similar total reflection phenomenon occurs if the material thickness is ½ n multiples of the light wavelength value (n=1,2,3 . . . ), or the interference phenomenon occurs if the material thickness is not ½ n multiples of the light wavelength. Reflection effect is reduced and anti-reflectivity capacity of the material is produced when interference occurs, and anti-reflectivity of the material is therefore achieved by controlling the material thickness. The thickness is considered an anti-reflective thickness when the material has anti-reflectivity to laser light in the present invention.

In the present embodiment, the heat-retaining layer 204 is controlled to have the anti-reflective thickness, and therefore the heat-retaining layer 204 has anti-reflectivity to the laser light 210. For example, the preferred anti-reflective thickness of the heat-retaining layer 204 is about 1300, 2200, 3100, 4000, 4900, or 5800 Å. Actually, the preferred anti-reflective thickness varies as different material of the heat-retaining layer 204 and different light source of the laser light 210.

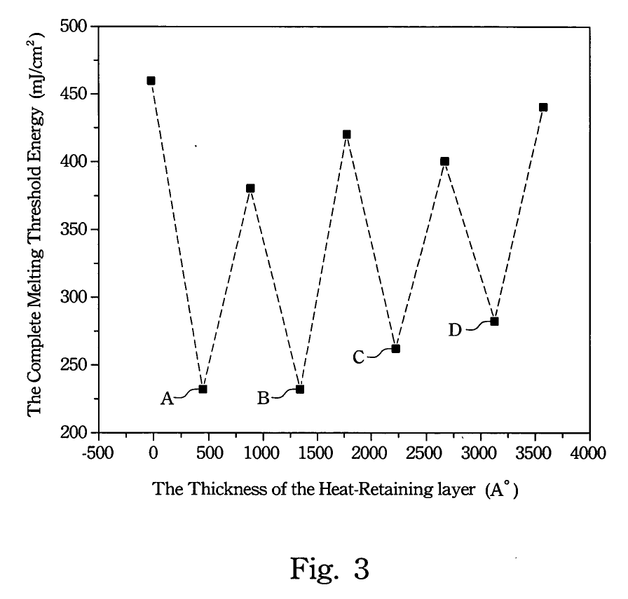

Referring to FIG. 3, FIG. 3 is a graph showing the relationship between the thickness of the heat-retaining layer 204 and the complete melting threshold energy of amorphous silicon in accordance with the first preferred embodiment of the present invention. The X-axis in FIG. 3 represents the thickness of the heat-retaining layer 204, and the Y-axis in FIG. 3 represents the threshold energy to effect the melting of the amorphous silicon layer 202. From FIG. 3, the threshold energy to effect the melting of the amorphous silicon layer 202 is different when the thickness of the heat-retaining layer 204 varies; the threshold energy to effect the melting of amorphous silicon is obviously lower at turning points A, B, C and D, and the thickness of the heat-retaining layer 204 at points A, B, C and D is anti-reflective thickness.

According to the diagram in FIG. 3, laser energy density used for melting the amorphous silicon layer 202 completely is reduced when the heat-retaining layer 204 has the anti-reflective thickness, and actual laser energy of the laser light 210 is thus reduced, or additional heating function of the heat-retaining layer 204 is further improved. For example, laser energy used in this present embodiment is only operated at 200-900 mJ/cm². Therefore, laser energy is utilized more effectively in the present embodiment, and uniformity of laser energy distributed in the amorphous silicon layer 202 is improved by the heat-retaining layer 204. Thus, high-repeated laser irradiation in a conventional laser annealing process is avoided, even a single shot laser can achieve a good crystallization result. Besides, a process window of laser energy control is broadened to about 100-200 mJ/cm² by employing the present embodiment.

Additionally, because laser energy density used for melting amorphous silicon completely is reduced by anti-reflection function from the heat-retaining layer 204, the irradiative area of one laser shot is increased. The frequency or the total number of laser shot used is thus decreased due to increased irradiative area when the laser irradiation process is performed for substrates with the same area, and more particularly, the frequency or the total number of laser shot used is decreased obviously for reducing the cost in large size TFT-LCD fabrication.

Although only one heat-retaining layer is utilized in the present embodiment, the present embodiment is not limited to use of only one heat-retaining layer, and the same material or different materials with semitransparent capability can be places on the single heat-retaining layer. The anti-reflective thickness control is employed to form a double-layer or multiple-layer heat-retaining structure having the same laser crystallization enhancement function.

### Embodiment 2

The present invention discloses another method of enhancing laser crystallization for polycrystalline silicon fabrication. Two heat-retaining layers are utilized to cap the amorphous silicon layer. Besides, anti-reflectivity to laser light is obtained by controlling the anti-reflective thickness of the two heat-retaining layers, and the two heat-retaining layers have a dielectric capability by choosing a suitable material as the heat-retaining layers for TFT device fabrication.

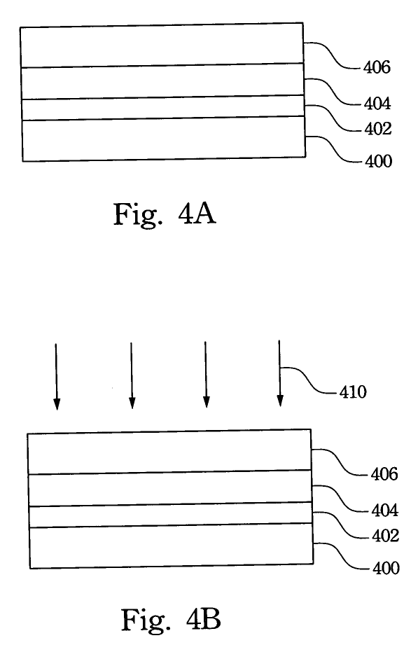

Referring to FIGS. 4A-4B, FIGS. 4A-4B are cross-sectional schematic diagrams showing the process for enhancing laser crystallization in accordance with the second preferred embodiment of the present invention. First, referring to FIG. 4A, an amorphous silicon layer 402 is formed on a substrate 400 by, for example, PECVD or PVD, and dehydrogenation is then performed on the amorphous silicon layer 402 to prevent a hydrogen explosion during the subsequent laser annealing.

Then, a first heat-retaining layer 404 and a second heat-retaining layer 406 are formed on the amorphous silicon layer 402 in turn. Wherein the first heat-retaining layer 404 has one anti-reflective thickness as the first embodiment, and the second heat-retaining layer 406 has another anti-reflective thickness.

The second heat-retaining layer 406 is a semitransparent material such as SiOₓN_{y}, used in the first embodiment, and the first heat-retaining layer 404 has not only semitransparency, but also a suitable dielectric capability for simultaneously serving as a dielectric interlayer. For example, the first heat-retaining layer 404 is made of silicon dioxide (SiO₂). Alternatively, a SiOₓN_{y} film can be used as the first heat-retaining layer 404 and a dielectric interlayer, simultaneously, by controlling composition ratio of SiOₓN_{y}.

Finally, a laser light 410 is utilized to perform a laser irradiation process, wherein the laser light 410 is, for example, a XeCl excimer laser. The amorphous silicon layer 402 is melted to crystallize for forming a polycrystalline silicon layer when portions of the laser light are transmitted to the amorphous silicon layer 402.

The first heat-retaining layer 404 and the second heat-retaining layer 406 have different anti-reflective thicknesses, and the anti-reflective thickness control is according to the material type. The anti-reflective behavior to the laser light 410 is more complex than that in the first embodiment. Actually, the laser energy transmission to the amorphous silicon layer 402 is simultaneously affected by the heat-retaining layer 404 and the heat-retaining layer 406.

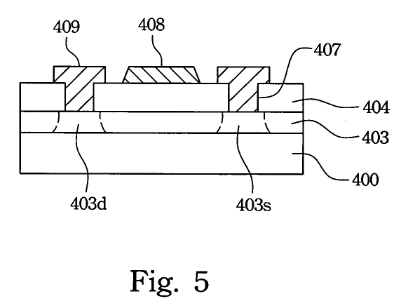

In the second embodiment, the second heat-retaining layer 406 can be removed after the laser irradiation process, and the general subsequent TFT process can next be applied to finish polycrystalline silicon TFT devices. For example, FIG. 5 is a cross-sectional schematic diagram showing the structure of the polycrystalline silicon TFT in accordance with the second preferred embodiment.

In FIG. 5, the polycrystalline silicon layer 403 is changed from the amorphous silicon layer 402 through the above process for laser crystallization, and the first heat-retaining layer 404 is used as a dielectric interlayer after removing the second heat-retaining layer 406. Wherein the first heat-retaining layer 404 is patterned to form contact holes 407 in the first heat-retaining layer 404, and the contact holes 407 expose the polycrystalline silicon layer 403. Next, a gate metal 408 is fabricated on the first heat-retaining layer 404, and the polycrystalline silicon layer 403 exposed in the contact holes 407 on sides of the gate metal 408 is ion implanted to form a source region 403s and a drain region 403d. Then, source/drain (S/D) metals 409 are fabricated in the contact holes 407 for contacting the source region 403s and the drain region 403d, respectively, and the structure finished in FIG. 5 is a polycrystalline silicon TFT.

In addition to the methods aforementioned, a single heat-retaining layer can be placed on the amorphous silicon layer for enhancing laser crystallization and serving as the dielectric interlayer simultaneously if SiOₓN_{y} film with suitable dielectricity is formed as the heat-retaining layer. Thus, the general subsequent TFT fabrication process is performed directly after laser irradiation to finish TFT devices without removing the heat-retaining layer.

According to the aforementioned preferred embodiments of the present invention, with the application of the present invention, a continuous heating function of the heat-retaining layer and the anti-reflective thickness control for the heat-retaining layer are utilized to enhance laser crystallization greatly. The melting time of the amorphous silicon layer is lengthened to improve grain growth for forming enlarged crystal grains, and the laser energy is utilized more effectively.

Further, with the heat-retaining layer and the anti-reflective thickness capacity combined, the laser energy density used is reduced, and laser energy distribution absorbed in the amorphous silicon layer is more uniform. Therefore, actual total laser energy used is reduced effectively, or the irradiative area of each laser shot is increased for decreasing the frequency or total number of laser shot used, and process cost is thus reduced greatly. Besides, frequently repeated laser operation in the conventional laser process is avoided; a single shot laser operation can achieve a good crystallization result.

Thus, a polycrystalline silicon layer with several micrometers grain size is obtained by employing the present invention. Compared with conventional crystallization methods, the polycrystalline silicon layer formed by the present invention has much better quality for fabricating TFT devices with higher performance.

The present invention is not limited to use in TFT fabrication for flat panel display; other polycrystalline silicon TFT devices or polycrystalline silicon layers also can be fabricated by using the present invention to improve production efficiency. While the present invention has been disclosed with reference to the preferred embodiments of the present invention, it should not be considered as limited thereby. Various possible modifications and alterations by one skilled in the art can be included within the spirit and scope of the present invention, the scope of the invention is determined by the claims that follow.

What is claimed is:

1. A method of enhancing laser crystallization for polycrystalline silicon fabrication, comprising the steps of:
forming an amorphous silicon layer on a substrate;
forming at least a heat-retaining layer on the amorphous silicon layer, wherein the heat-retaining layer has an anti-reflective thickness for reducing a threshold laser energy to effect melting of the amorphous silicon layer; and
Irradiating the amorphous silicon layer with at least a laser pulse to transform the amorphous silicon layer into a polycrystalline silicon layer, wherein a portion of laser energy transmits the heat-retaining layer, and another portion of laser energy is absorbed by the heat-retaining layer.

2. The method of claim 1, wherein the step of forming the amorphous silicon layer comprises plasma enhanced chemical vapor deposition (PECVD) or physical vapor deposition (PVD).

3. The method of claim 1, wherein the heat-retaining layer is a semitransparent thin film for the laser pulse.

4. The method of claim 3, wherein the heat-retaining layer is made of silicon oxynitride (SiOₓN_{y}).

5. The method of claim 1, wherein the irradiating step comprises using an ultraviolet excimer laser pulse.

6. The method of claim 1, wherein the anti-reflective thickness of the heat-retaining layer is close to 1300 Å, 2200 Å, 3100 Å, 4000 Å, 4900 Å or 5800 Å.

7. The method of claim 1, further comprising the steps of:
patterning the heat-retaining layer to form a plurality of contact holes in the heat-retaining layer, wherein the contact holes expose portions of the polycrystalline silicon layer; and
forming at least a gate metal and a plurality of source/drain metals, wherein the gate metal is on the heat-retaining layer, and the source/drain metals are in the contact holes.

8. The method of claim 7, wherein the heat-retaining layer is used as a dielectric interlayer.

9. The method of claim 1, further comprising the steps of:
removing the heat-retaining layer to expose the polycrystalline silicon layer;
forming a dielectric interlayer on the polycrystalline silicon layer;
patterning the dielectric interlayer to form a plurality of contact holes in the dielectric interlayer, wherein the contact holes expose portions of the polycrystalline silicon layer; and
forming at least a gate metal and a plurality of source/drain metals, wherein the gate metal is on the dielectric interlayer, and the source/drain metals are in the contact holes.

10. The method of claim 1, wherein the irradiating step comprises laser energy of about 200-900 mJ/cm².

11. A method of enhancing laser crystallization for polycrystalline silicon fabrication, comprising the steps of:
forming an amorphous silicon layer on a substrate;
forming a first heat-retaining layer on the amorphous silicon layer;
forming at least a second heat-retaining layer on the first heat-retaining layer, wherein the first heat-retaining layer and the second heat-retaining layer have a first anti-reflective thickness and a second anti-reflective thickness respectively for reducing a threshold laser energy to effect melting of the amorphous silicon layer, and the first heat-retaining layer has dielectric capability; and
Irradiating the amorphous silicon layer with at least a laser pulse to transform the amorphous silicon layer into a polycrystalline silicon layer, wherein a portion of laser energy transmits the first heat-retaining layer and the second heat-retaining layer, and another portion of laser energy is absorbed by both the first heat-retaining layer and the second heat-retaining layer.

12. The method of claim 11, wherein the first heat-retaining layer and the second heat-retaining layer are semitransparent thin films for the laser pulse.

13. The method of claim 12, wherein the first heat-retaining layer is made of silicon dioxide (SiO₂) or silicon oxynitride (SiOₓN_{y}).

14. The method of claim 12, wherein the second heat-retaining layer is made of silicon oxynitride (SiOₓN_{y}).

15. The method of claim 11, wherein the irradiating step comprises using an ultraviolet excimer laser pulse.

16. The method of claim 11, further comprising the steps of:
removing the second heat-retaining layer to expose the first heat-retaining layer completely;
patterning the first heat-retaining layer to form a plurality of contact holes in the first heat-retaining layer, wherein the contact holes expose portions of the polycrystalline silicon layer; and
forming at least a gate metal and a plurality of source/drain metals, wherein the gate metal is on the first heat-retaining layer, and the source/drain metals are in the contact holes.

17. The method of claim 11, wherein the irradiating step comprises laser energy of about 200-900 mJ/cm².

18. A method of fabricating a polycrystalline silicon thin film transistor, comprising the steps of:
forming an amorphous silicon layer on a substrate;
forming a first heat-retaining layer on the amorphous silicon layer;
forming at least a second heat-retaining layer on the first heat-retaining layer, wherein the first heat-retaining layer and the second heat-retaining layer have a first anti-reflective thickness and a second anti-reflective thickness respectively for reducing a threshold laser energy to effect melting of the amorphous silicon layer, and the first heat-retaining layer has dielectric capability;
Irradiating the amorphous silicon layer with at least a laser pulse to transform the amorphous silicon layer into a polycrystalline silicon layer, wherein a portion of laser energy transmits the first heat-retaining layer and the second heat-retaining layer, and another portion of laser energy is absorbed by both the first heat-retaining layer and the second heat-retaining layer;
removing the second heat-retaining layer to expose the first heat-retaining layer completely;
patterning the first heat-retaining layer to form a plurality of contact holes in the first heat-retaining layer, wherein the contact holes expose portions of the polycrystalline silicon layer; and
forming at least a gate metal and a plurality of source/drain metals, wherein the gate metal is on the first heat-retaining layer, and the source/drain metals are in the contact holes.

19. The method of claim 18, wherein the first heat-retaining layer is made of silicon dioxide (SiO₂) or silicon oxynitride (SiOₓN_{y}).

20. The method of claim 18, wherein the second heat-retaining layer is made of silicon oxynitride (SiOₓN_{y}).
